(19) United States
(12) Patent Application Publication
(10) Pub. No.: US 2016/0128242 A1
(43) Pub. Date: May 5, 2016

(54) GASKET INSTALLATION FIXTURE

(71) Applicants: FU TAI HUA INDUSTRY (SHENZHEN) CO., LTD., Shenzhen (CN); HON HAI PRECISION INDUSTRY CO., LTD., New Taipei (TW)

(72) Inventors: MING-YONG WU, Shenzhen (CN); ZHI-BING JIANG, Shenzhen (CN); GUANG YANG, Shenzhen (CN)

(21) Appl. No.: 14/669,591

(22) Filed: Mar. 26, 2015

(30) Foreign Application Priority Data
Nov. 4, 2014 (CN) 201410611438.3

(51) Int. Cl. H05K 13/00; F16J 15/06

(52) U.S. Cl. CPC H05K 13/0007; F16J 15/061

(57) ABSTRACT

A gasket installation fixture includes a shell and a positioning mechanism which is fixed on the shell. The positioning mechanism defines a pressing block and a transmission mechanism which is received in the shell. The transmission mechanism defines a slope and a guiding column which is received in the transmission mechanism, when the pressing block pushes against the slope, the transmission mechanism can slide in the shell to elastically deform and the guiding column can expand to hold and press the gasket into its place.

### CROSS-REFERENCE TO RELATED APPLICATIONS

This application claims priority to Chinese Patent Application No. 201410611438.3 filed on Nov. 4, 2014 in the China Intellectual Property Office, the contents of which are incorporated by reference herein.

### FIELD

The disclosure generally relates to handling techniques.

### BACKGROUND

In some production processes, in order to improve the gas tightness of the device, the gasket-like element needs to be fixed on an opening of the device. Elastic deformation of the gasket is used to improve the gas tightness of the electronic device.

Usually, the gasket is installed on the opening of the electronic device manually one by one, which is time consuming and has a low production efficiency.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric, exploded view of an embodiment of a gasket installation fixture and a gasket.

FIG. 2 is similar to FIG. 1, but the gasket installation fixture is viewed from another aspect.

FIG. 3 is an isometric, assembled view of the gasket installation fixture and the gasket of FIG. 1.

FIG. 4 is a cutaway, cross sectional view along a line IV-IV of FIG. 3, which shows a movable pole of the gasket installation fixture in one position.

FIG. 5 is a cutaway, cross sectional view along a line IV-IV of FIG. 3, which shows the movable pole in another position.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The term “comprising,” when utilized, means “including, but not necessarily limited to”; it specifically indicates open-ended inclusion or membership in the so-described combination, group, series and the like.

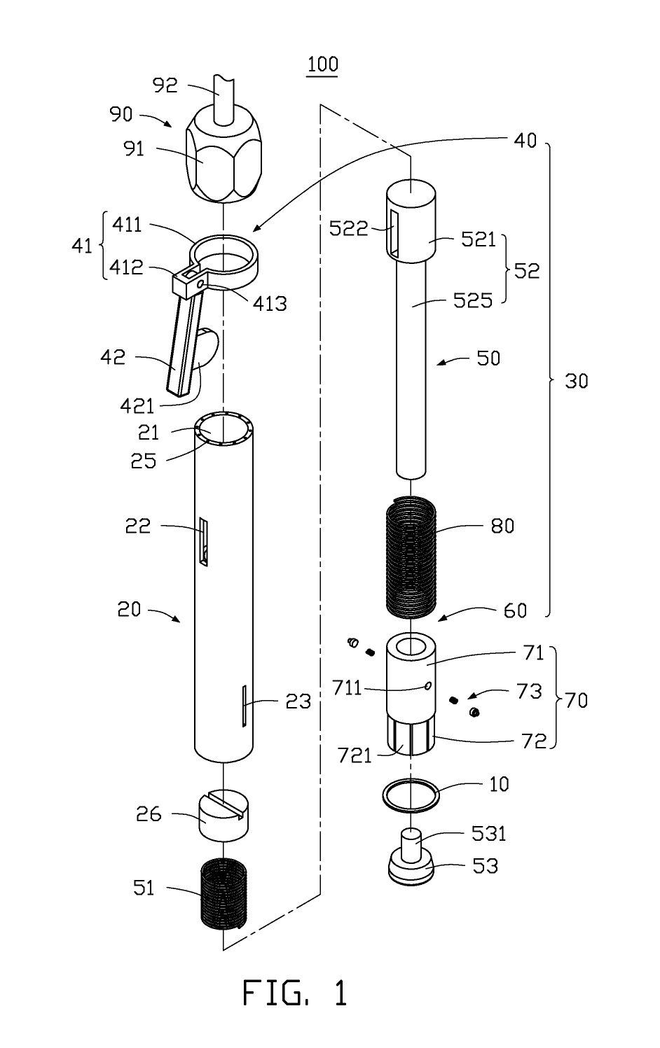

FIG. 1 illustrates one embodiment of a gasket installation fixture 100. The gasket installation fixture 100 is used to fix a gasket 10 on a base plate (not shown in FIGS). The gasket installation fixture 100 includes a shell 20, a positioning module 30 which is fixed on the shell 20, and a suction module 90.

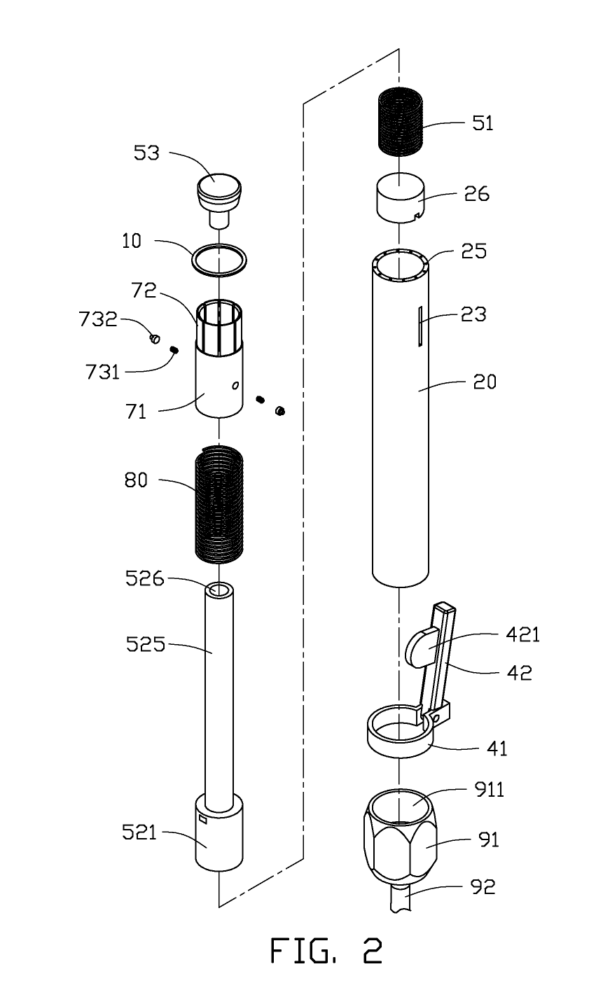

Referring to FIGS. 1 and 2, the gasket 10 is made of elastic material and can be elastically deformed. The gasket 10 is generally a circular shape. The base plate defines a plurality of fixing holes (not shown in FIGS), the gasket 10 can be installed on boundary of the fixing hole of the base plate.

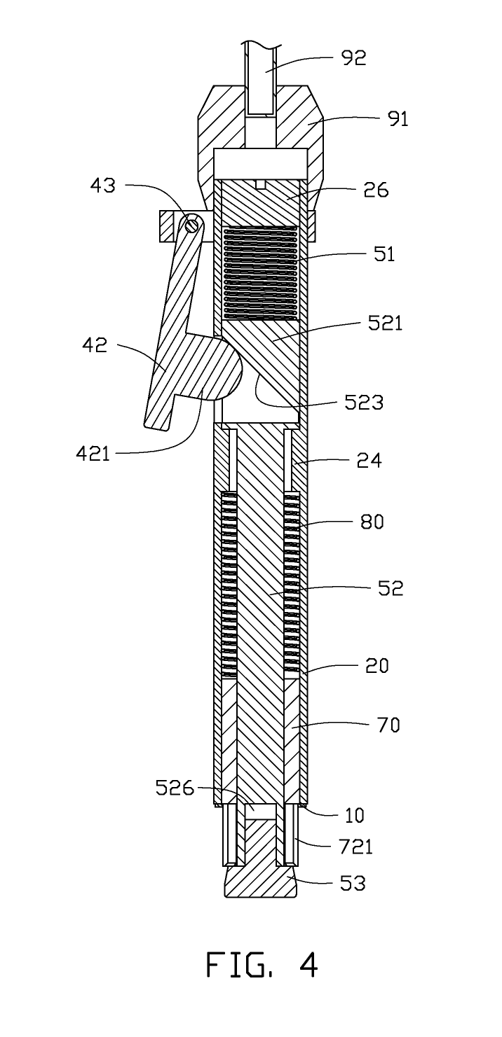

The shell 20 is generally a cylindrical shape and its interior is a hollow structure. The shell 20 defines a through hole 21 extending through the shell 20 in an axial direction. A first resisting groove 22 and two second resisting grooves 23 are defined on a side wall of the shell 20 to communicate with the through hole 21. The two second resisting grooves 23 are aligned in a line. The interior of the shell 20 is equipped with a clasp ring 24 (referring to FIG. 4). The clasp ring 24 is used to latch the positioning module 30. The shell 20 also defines a plurality of suction holes 25, the suction holes 25 being defined in the side wall of the shell 20 and extending through the side wall of the shell 20 in the axial direction of shell 20. The suction hole 25 is used to vacuum-lift the gasket 10. One side of the shell 20 is equipped with a stopper block 26. The stopper block 26 can be fixed in the through holes 21.

The positioning module 30 includes a positioning mechanism 40, a transmission mechanism 50 and a guiding mechanism 60. The positioning mechanism 40 includes a fixing piece 41, a movable pole 42 and a rotation shaft 43 (referring to FIG. 4). The fixing piece 41 includes a fastener ring 411 and a fixing portion 412. The fastener ring 411 is fixed on the shell 20. The fixing portion 412 defines two pivot holes 413. One side of the movable pole 42 defines a connecting hole (not shown in FIGS), another side of the movable pole 42 defines a pressing block 421. The pressing block 421 can pass through the first resisting groove 22 and go into the shell 20. The rotation shaft 43 can pass through the pivot hole 413 and the connecting hole to pivotally mount the movable pole 42 to the fixing piece 41.

The transmission mechanism 50 includes a first elastic member 51, a transmission shaft 52, and a cap 53. The first elastic member 51 is received in the through hole 21 and one end of the first elastic member 51 resists against the stopper block 26. The transmission shaft 52 includes a transmission portion 521 and a connecting portion 525. The transmission portion 521 defines a receiving groove 522. The receiving groove 522 defines a slope 523 (referring to FIG. 4). The pressing block 421 can be received in the receiving groove 522 and can push against the slope 523. One side of the connecting portion 525 defines a notch 526. The cap 53 is equipped with a protrusion 531. The protrusion 531 is inserted into the notch 526 to fix the cap 53 on the transmission shaft 52.

The guiding mechanism 60 includes a guiding column 70 and a second elastic member 80. The guiding column 70 includes a guiding portion 71, a swelling portion 72 which is connected with the guiding portion 71, and two sliding pieces 73 which are fixed on the guiding portion 71. The guiding portion 71 defines two receiving holes 711. The swelling portion 72 includes a plurality of elastic pieces 721. An elastic piece 721 can be elastically deformed to expand outwardly. The sliding piece 73 includes a spring 731 and a sliding block 732. One end of the spring 731 is fixed in the receiving hole 711 and another end of the spring 731 is fixed on the sliding block 732 to fix the sliding piece 73 on the guiding portion 71. The sliding block 762 can slide in the second resisting groove 23. The second elastic member 80 is received in the shell 20. One side of the elastic member 80 abuts the clasp ring 24. Another side of the elastic member 80 abuts the guiding column 70.

The suction module 90 includes an adapter 91, and a pipeline 92 which is connected with the adapter 91. The adapter 91 defines a dent 911. The shell 20 can be inserted into the dent 911 to fix the adapter 91 on the shell 20.

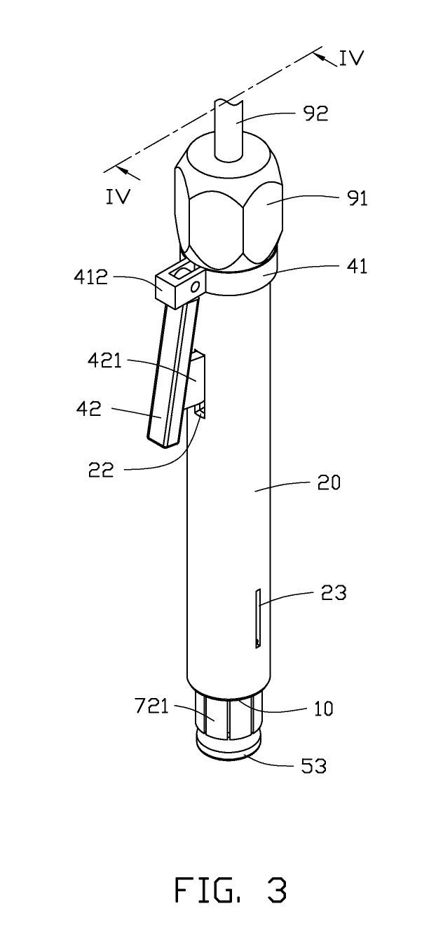

FIGS. 3 and 4 illustrate that, in assembly, the shell 20 is inserted into the fastener ring 411. The pressing block 421 is aligned to the first resisting groove 22 of the shell 20. The connecting hole of the movable pole 42 is aligned with the pivot hole 413 of the fixing piece 41. The rotation shaft 43 passes through the pivot hole 413 and the connecting hole, to pivotally mount the movable pole 42 on the fixing piece 41, and simultaneously tighten the fastener ring 411 to secure the 40 on the shell 20.

The connecting portion 525 of the transmission shaft 52 is inserted into the through hole 21 until the transmission portion 521 abuts the clasp ring 24. The transmission shaft 52 is rotated to align the receiving groove 522 with the first resisting groove 22. The first elastic member 51 is placed in the through hole 21 with one end of the first elastic member 51 resisting against the transmission portion 521. The stopper block 26 is placed in the through hole 21 and resists against another end of the first elastic member 51.

The two sliding pieces 73 are fixed in the two receiving holes 711 of the guiding column 70. The second elastic member 80 and the guiding portion 71 of the guiding column 70 are inserted into the through hole 21. When the second elastic member 80 abuts the clasp ring 24, the spring 731 is elastically deformed and moves the sliding block 732 into the through hole 21 until the sliding block 732 is aligned with the second resisting groove 23. The spring 731 elastically restores and the sliding block 732 is received in the second resisting groove 23, and the second elastic member 80 and the guiding column 70 are all received in the transmission shaft 52. The protrusion 531 is inserted into the notch 526 of the connecting portion 525 to fix the cap 53 on the transmission shaft 52. Then, the transmission mechanism 50 and the guiding mechanism 60 are all installed in the shell 20.

The dent 911 of the adapter 91 is aligned with the one side of the shell 20 which defines the stopper block 26. The shell 20 is inserted into the dent to fix the adapter 91 on the shell 20. The pipeline 92 is connected with the adapter 91. The assembly of the gasket installation fixture 100 is thus complete.

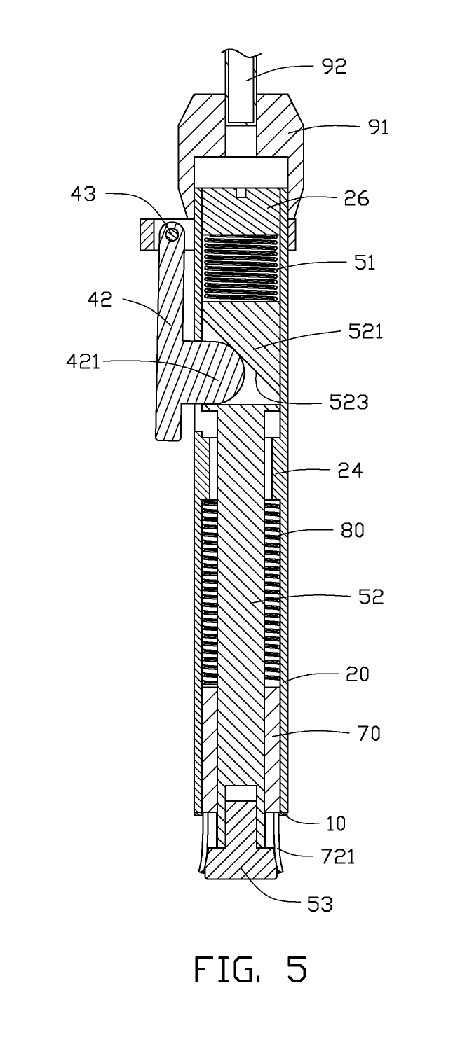

Referring to the FIGS. 4 and 5, when the gasket 10 need to be installed on the base, the cap 53 passes through the gasket 10 until the suction hole 25 contacts the gasket 10. The pipeline 92 can evacuate the gas in the suction hole 25 so the gasket is adsorbed on the shell 20. The gasket installation fixture 100 is inserted into the fixing hole, the cap 53 and the swelling portion 72 pass through the fixing hole, and the gasket 10 contacts the fixing hole. The movable pole 42 is rotated, the pressing block 421 pushes against the slope 523 of the receiving groove 522, the transmission shaft 52 is slid along the first elastic member 51, and the first elastic member 51 is compressed. The cap 53 is inserted into the swelling portion 72 under the driven transmission shaft 52, and the elastic piece 721 is elastically deformed and expanded outwards. The gasket 10 is in close contact with the fixing hole under the pressure of the elastic piece 721. The movable pole 42 not moving, the shell 20 is pushed along the gasket 10, and the second elastic member 80 is compressed to fix the gasket 10 with the base. The gasket 10 is thereby fixed on the base. The movable pole 42 is rotated, the pressing block 421 is disengaged from the slope 523, the first elastic member 51 elastically recovers to push the transmission shaft 52, the cap 53 is disengaged from the swelling portion 72, and the spring 721 elastically recovers and disengages from the gasket 10. The gasket installation fixture 100 is thereby disengaged from the gasket 10.

In the above gasket installation fixture 100, the shell 20 is equipped with the positioning mechanism 40, transmission shaft 52, and the guiding column 70, the transmission shaft 52 defining the slope 523. The pressing block 421 of the movable pole 42 pushes against the slope 523 to move the transmission shaft 52, the guiding column 70 is elastically deformed and expanded to steadily hold and press the gasket 10 on the fixing hole of the base.

It is to be understood, however, that even though numerous characteristics and advantages of the embodiments have been set forth in the foregoing description, together with details of the structure and functions of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. A gasket installation fixture, comprising:
a shell;
a positioning mechanism fixed on the shell, the positioning mechanism defining a pressing block;
a transmission mechanism received in the shell, the transmission mechanism defining a slope; and
a guiding column received in the transmission mechanism;
wherein the transmission mechanism is configured to slide in the shell to elastically deform and expand towards the guiding column when the pressing block pushes the slope.

2. The gasket installation fixture of claim 1, wherein the shell defines a first resisting groove, the pressing block passes through the first resisting groove and resists against the slope.

3. The gasket installation fixture of claim 2, wherein the positioning mechanism comprises a fixing piece, the fixing piece is fixed on the shell to fix the positioning mechanism on the shell.

4. The gasket installation fixture of claim 1, wherein the positioning mechanism comprises a movable pole which is equipped with the pressing block, the movable pole is rotationally installed on the fixing piece.

5. The gasket installation fixture of claim 4, wherein the fixing piece defines a pivot hole, the movable pole defines a connecting hole, a rotation shaft passes through the pivot hole and the connecting hole to rotationally install the movable pole on the fixing piece.

6. The gasket installation fixture of claim 1, wherein the transmission mechanism comprises a transmission shaft, the transmission shaft defines a receiving groove, the slope is set on the receiving groove.

7. The gasket installation fixture of claim 6, wherein the transmission mechanism further comprises a first elastic member which is relied on the transmission shaft, when the pressing block is divorced from the slope, the first elastic member elastically recovers to push the transmission shaft.

8. The gasket installation fixture of claim 7, wherein the transmission mechanism further comprises a cap which is fixed on the one side of the transmission shaft, when the transmission is pushed, the cap is inserted into the guiding column to elastically deform and the guiding column expend towards.

9. The gasket installation fixture of claim 1, wherein the guiding column comprises a swelling portion, the swelling portion comprises a plurality of elastic pieces, these elastic pieces can elastically deform and expend towards.

10. A gasket assembly, comprising:
a gasket;
a base plate; and
a gasket installation fixture which is used to install the gasket on the base plate, the gasket installation fixture including a shell which is used to adsorb the gasket, a positioning mechanism which is fixed on the shell, a transmission mechanism which is received in the shell and a guiding column which is received in the transmission mechanism, the positioning mechanism comprises a pressing block, the transmission mechanism comprising a slope, and the gasket set on the guiding column.
wherein the transmission mechanism is configured to slide in the shell to elastically deform and expand towards the guiding column when the pressing block pushes the slope, the gasket is closely connected with the base plate and fixed on the base plate.

11. The gasket assembly of claim 10, wherein the shell defines a first resisting groove, the pressing block passes through the first resisting groove and resists against the slope.

12. The gasket assembly of claim 11, wherein the positioning mechanism comprises a fixing piece, the fixing piece is fixed on the shell to fix the positioning mechanism on the shell.

13. The gasket assembly of claim 10, wherein the positioning mechanism comprises a movable pole which is equipped with the pressing block, the movable pole is rotationally installed on the fixing piece.

14. The gasket assembly of claim 13, wherein the fixing piece defines a pivot hole, the movable pole defines a connecting hole, a rotation shaft passes through the pivot hole and the connecting hole to rotationally install the movable pole on the fixing piece.

15. The gasket assembly of claim 10, wherein the transmission mechanism comprises a transmission shaft, the transmission shaft defines a receiving groove, the slope is set on the receiving groove.

16. The gasket assembly of claim 15, wherein the transmission mechanism further comprises a first elastic member which is relied on the transmission shaft, when the pressing block is divorced from the slope, the first elastic member elastically recovers to push the transmission shaft.

17. The gasket assembly of claim 16, wherein the transmission mechanism further comprises a cap which is fixed on the one side of the transmission shaft, when the transmission is pushed, the cap is inserted into the guiding column to elastically deform and the guiding column expend towards.

18. The gasket assembly of claim 10, wherein the guiding column comprises a swelling portion, the swelling portion comprises a plurality of elastic pieces, these elastic pieces can elastically deform and expend towards.
